(19) United States
(12) Patent Application Publication
(10) Pub. No.: US 2014/0030636 A1
(43) Pub. Date: Jan. 30, 2014

(54) CORROSION RESISTANT CURRENT COLLECTOR UTILIZING GRAPHENE FILM PROTECTIVE LAYER

(71) Applicants: Xin Zhao, Wappingers Falls, NY (US); Yu-Ming Lin, West Harrison, NY (US)

(72) Inventors: Xin Zhao, Wappingers Falls, NY (US); Yu-Ming Lin, West Harrison, NY (US)

(73) Assignee: Bluestone Global Tech, Wappingers Falls, NY (US)

(21) Appl. No.: 13/559,112

(22) Filed: Jul. 26, 2012

(51) Int. Cl. B32B 9/00; B32B 15/04; H01L 31/0224; B05D 5/12; C25F 5/00; H01G 9/04; H01G 9/155; H01M 4/66; B32B 38/10; B82Y 99/00; B82Y 30/00; B82Y 40/00

(52) U.S. Cl. 429/521; 429/210; 428/457; 428/408; 136/252; 427/122; 216/6; 205/704; 361/500; 361/502; 977/734; 977/843; 977/948

(57) ABSTRACT

In general, in one aspect, a graphene film is used as a protective layer for current collectors in electrochemical energy conversion and storage devices. The graphene film inhibits passivation or corrosion of the underlying metals of the current collectors without adding additional weight or volume to the devices. The graphene film is highly conductive so the coated current collectors maintain conductivity as high as that of underlying metals. The protective nature of the graphene film enables less corrosion resistant, less costly and/or lighter weight metals to be utilized as current collectors. The graphene film may be formed directly on Cu or Ni current collectors using chemical vapor deposition (CVD) or may be transferred to other types of current collectors after formation. The graphene film coated current collectors may be utilized in batteries, super capacitors, dye-sensitized solar cells, and fuel and electrolytic cells.

### BACKGROUND

Conventional electrochemical energy storage devices (e.g., batteries, super capacitors) and energy conversion devices (e.g., dye-sensitized solar cells, fuel and electrolytic cells) consist of a pair of electrodes (positive and negative) separated by an electrolyte (e.g., polymer gel electrolyte, perforated or microporous polymeric membrane soaked in a liquid electrolyte). The electrode materials are usually coated on metallic foils that are used to collect the charge generated during discharge, and to permit connection to an external power source during recharge. The charge transfer reactions and electrolyte decomposition in the proximity of the current collectors usually result in corrosion behavior during cycling. The corrosion behavior may include one or more of: oxidization of current collectors at the positive electrode side (e.g., formation of thick surface oxide layers); ion intercalation at the negative electrode side (e.g., plating of metallic alloys and subsequent pulverization of current collectors); and etch and dissolution of exposed current collector surface. The corrosion behavior may result in passivation of the current collectors resulting in increased internal resistance and voltage drop at high current loading, or deterioration in device lifetime, performance and ultimate collapse during successive charge/discharge cycling.

Current energy and environmental concerns are driving the development of energy storage devices towards the fields demanding high power output, such as electrical automotives, integration of renewable energy and smart electric grids. To meet the operation requirements, these energy storage devices need to have fast charge/discharge capability at high load current, and possess low internal resistance to suppress voltage degradation and energy dissipation in the form of waste heat. Accordingly, high-quality metals that are less susceptible to corrosion are required to be used as current collectors. Current collectors in conventional energy conversion and storage devices are usually limited to copper (Cu) for the negative side and aluminum (Al) for the positive side in non-aqueous electrolytes, or platinum (Pt), stainless steel and iron-nickel (Fe—Ni) alloy in aqueous electrolytes.

To further achieve high power density and long lifetime, additional treatments are necessary to diminish corrosion at the current collectors. For example, introduction of non-corrodible conducting metal powders into electrode materials, or plating non-corrodible metal coatings onto current collectors facing the electrode sides. However, substantial quantities of noble metals such as silver, gold or platinum are needed to ensure long-term robustness. Another strategy is to induce electrically conducting organic protective layers onto current collectors or organic additives into the electrolytes. All these attempts led to significant increases in the cost and manufacture complexity of the final devices.

### BRIEF DESCRIPTION OF THE DRAWINGS

The features and advantages of the various embodiments will become apparent from the following detailed description in which:

FIGS. 1A-1C illustrate an example process of forming a corrosion resistant current collector/electrode for use in energy conversion and storage devices, according to one embodiment;

FIGS. 2A-2F illustrate an example process for transferring the graphene film from the current collector it was grown on to a different current collector, according to one embodiment;

FIG. 3 illustrates a high level representation of an example energy conversion and/or storage device, according to one embodiment; and

FIG. 4 illustrates a high level representation of an example energy conversion and/or storage device, according to one embodiment.

### DETAILED DESCRIPTION

Graphene is an allotrope of carbon. Its structure is one-atom-thick planar sheets of sp²-bonded carbon atoms that are densely packed in a honeycomb crystal lattice. A graphene film may be made of a single graphene sheet or several layers of graphene sheets. The graphene film may be impermeable to gas and ion diffusion and have excellent chemical and mechanical stability. The graphene film may therefore be used as anti-corrosion protective layers for metallic current collectors in electrochemical energy conversion and storage devices. The graphene film may be a continuous coating inserted between electrode materials (anode and cathode) and a corresponding face of the metallic current collector. Alternatively, the graphene film may cover the entire current collector. The use of graphene film provides protective layers that are efficient and reliable in inhibiting passivation or corrosion of the underlying metals without adding additional weight or volume to the system.

Furthermore, the graphene film is highly conductive. Thus, the coated current collectors maintain conductivity as high as that of fresh metals. The mobility of charge carriers (electrons) between the current collectors and electrode materials can readily pass through the conducting graphene intermediate. This represents an attractive pathway to enhance the power delivery and cycling life of energy conversion and storage devices. Moreover, it may enable additional choices in the metals utilized for the current collectors. For example, less costly and/or lighter weight metals may be utilized.

The graphene film may be grown on metal films, such as copper (Cu) or nickel (Ni), by a chemical vapor deposition (CVD) process. CVD processes are known to those skilled in the art. The CVD process may be conducted between approximately 500 and 1200 degrees Celsius (° C.).

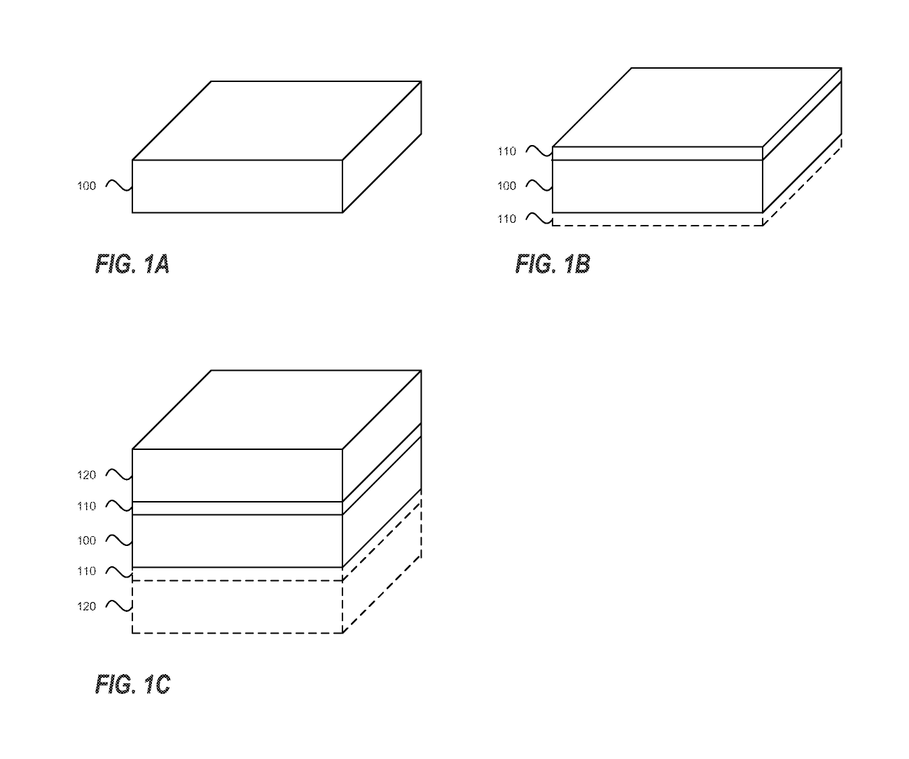

FIGS. 1A-1C illustrates an example process of forming a corrosion resistant current collector/electrode for use in energy conversion and storage devices. FIG. 1A illustrates the process beginning with a metal layer 100 (e.g., Cu, Ni). FIG. 1B illustrates the metal layer 100 after a graphene film 110 is grown thereon using CVD. The graphene film 110 acts as a protective layer and may be a single graphene sheet or several layers of graphene sheets. As illustrated, the graphene film 110 was grown on both sides of the metal layer 100 and covers the entire surface of each side. According to one embodiment, the graphene film 110 may be removed from one side and utilized elsewhere. Alternatively, the graphene film 110 may be grown on a single side. The graphene film 110 on bottom side is illustrated in dotted lines to indicate it is optional. The resultant coated metallic substrate 100, 110 may serve as passivation/corrosion inhibitive current collectors in energy conversion and/or storage devices. The coated metallic substrates 100, 110 may be applied to the energy conversion and/or storage devices directly.

FIG. 1C illustrates the coated metallic substrate 100, 110 after electrode materials 120 are coated onto the graphene film 110. The electrode materials 120 may be coated on a side that will face electrolyte in an energy conversion and storage devices. According to one embodiment, the electrode materials 120 may be coated on both sides of the substrate. The electrode materials 120 on bottom side are illustrated in dotted lines to indicate it is optional. The metallic substrate 100 having electrode materials 120 on both sides may, for example, be utilized between multi-stacked electrodes or cells where it acts as a cathode on one side and an anode on the other side.

The electrode materials may include, but are not limited to, graphite, lithium iron phosphate, nickel oxide, manganese oxide, titanium oxide and alkaline metal hydride. The electrode materials may be coated thereon by tape casting, hot pressing, sputtering or thermal deposition. The processes for coating the electrode materials may be known to those skilled in the art. The type of electrode materials 120 used may be based on amongst other things the type of energy conversion and storage device the resultant current collector/electrode 100, 110, 120 are to be used in and whether the electrode is an anode or cathode. For the embodiment where the electrode materials 120 are on both sides, the electrode materials 120 on the two sides may be the same or may be different depending on the use thereof.

The use of the graphene film 110 between the current collector 100 and the electrode material 120 may inhibit passivation or corrosion of the current collector 100 that may typically occur without affecting the conductivity thereof or adding any noticeable weight or volume thereto.

The current collectors 100 (e.g., Cu, Ni) may be utilized in energy conversion and storage devices when appropriate. However, some devices may be better served with a different metal layer, such as an aluminum (Al) or iron (Fe). Furthermore, the use of the graphene film 110 may enable arbitrary metals to be utilized as current collectors. The arbitrary metals may be more susceptible to corrosion, may be lighter weight, and/or may be less expensive. The graphene film 110 grown via CVD on the metal layer 100 (e.g., Cu, Ni) may be mechanically transferred to other metal layers.

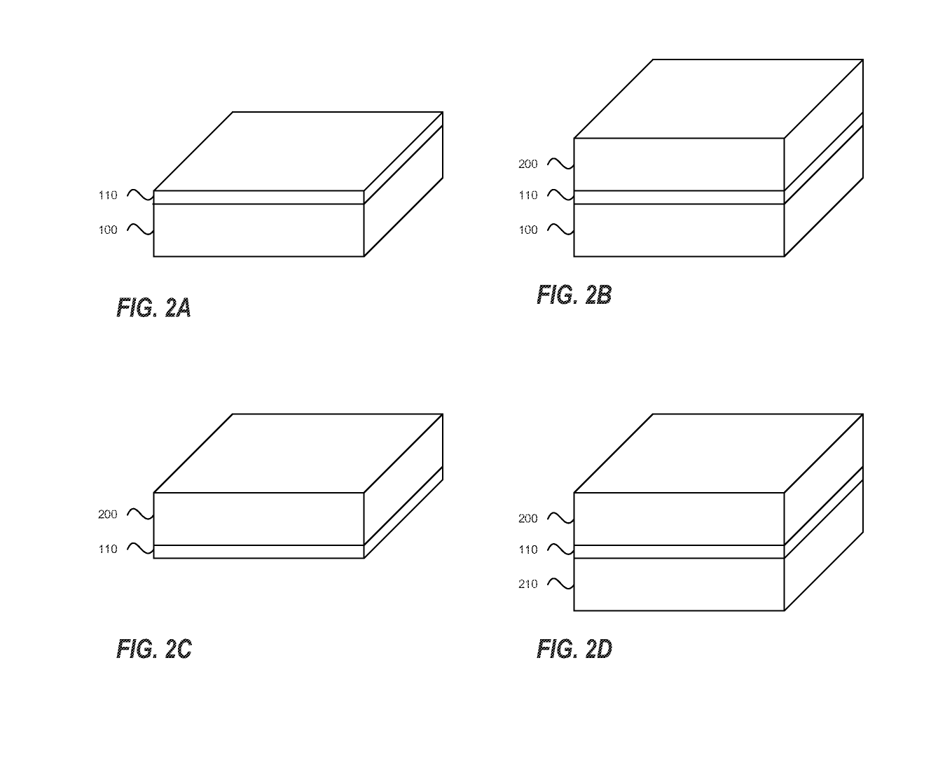

FIGS. 2A-F illustrate an example process for transferring the graphene film 110 from the current collector (e.g., Cu, Ni) it was grown on to a different current collector. FIG. 2A illustrates the metallic substrate 100 (e.g., Cu, Ni) coated with the graphene film 110 on one side as a starting point (e.g., FIG. 1B). FIG. 2B illustrates the substrate after a photoresist film 200 is casted onto the graphene film 110 by spray coating, dip coating, spin coating, casting or lamination. The photoresist film 200 may be a polymethyl methacrylate (PMMA) film but is not limited thereto. These processes are known to those skilled in the art. Following the application of the photoresist film 120 the substrate is dried or baked to enhance adhesion between the graphene 110 and the photoresist film 200.

FIG. 2C illustrates the substrate after the metal layer 100 (e.g., Cu, Ni) is removed leaving the graphene film 110 coated with the photoresist film 200 on one side and nothing on the other side. The metal layer 100 may be etched off using any number of etching methods, including dry etching or wet etching, known to those skilled in the art. If the metal layer 100 is etched it cannot be reused which may increase the overall cost of the resulting current collector/electrode. Alternatively, the graphene film 110 may be detached from the metal layer 100 by electrochemical peeling which is known to those skilled in the art. If the graphene film 110 is peeled off of the metal layer 100, it can be reused to grow additional graphene films 110.

FIG. 2D illustrates the substrate after the released side of graphene film 110 is attached to a target metal substrate 210. The target metal substrate 210 may be selected based on various parameters, including but not limited to, the type of energy conversion and/or storage device the resultant current collector/electrode are to be used in, whether the electrode is an anode or cathode, the price point for the device, the weight requirements of the device. For example, the target metal substrate 210 may be Al, Fe, or any number of other metals that are not as high quality as the standard metals used for current collectors and may be cheaper and lighter weight metals. The graphene film 110 may be attached to the target metal substrate 210 directly upon drying or using known methods including the use of extrusion equipment to strengthen the adhesion.

FIG. 2E illustrates the substrate after removal of the photoresist film 200. The photoresist film 200 may be removed using known methods, including but not limited to, rinsing the substrate in a solvent, such as acetone or annealing in air. The substrate may be dried before incorporation into electrodes. The graphene transfer procedure can be repeated upon needs to create coatings on both sides of the metal substrate 210. The graphene film 110 on bottom side is illustrated in dotted lines to indicate it is optional.

FIG. 2F illustrates the substrate after electrode materials 220 are coated onto the graphene film 110. As noted above, the electrode materials 220 may be coated either on one side or on both sides. The electrode materials 220 on bottom side are illustrated in dotted lines to indicate it is optional. The electrode materials may include, but are not limited to, graphite, lithium iron phosphate, nickel oxide, manganese oxide, titanium oxide and alkaline metal hydride. The electrode materials may be coated thereon by tape casting, hot pressing, sputtering or thermal deposition. The processes for coating the electrode materials may be known to those skilled in the art. The type of electrode materials 220 used may be based on various different parameters. The electrode materials 220 may be the same as the electrode materials 120 utilized for the current collectors 100 (e.g., Cu, Ni) or may be different based on the different material used for the current collector 210. For the embodiment where the electrode materials 220 are on both sides, the electrode materials 220 on the two sides may be the same or may be different.

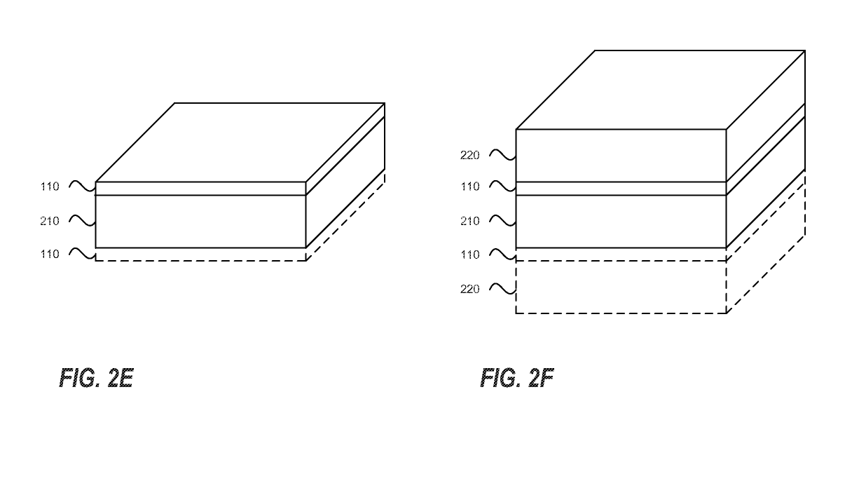

FIG. 3 illustrates a high level representation of an example energy conversion and/or storage device 300. The device 300 includes a pair of current collectors 310, 315 each having a surface covered with a graphene film 320. The current collectors 310, 315 are metallic conductor layers. The current collectors 310, 315 may be made of the same metal or may be made of different metals (current collector 310 may be made of a first material while the current collector 315 is made of a second material). The current collectors 310, 315 may be Cu or Ni, where the graphene film 320 was grown thereon (e.g., FIGS. 1A-1B). Alternatively, the current collectors 310, 315 may be an arbitrary metal, where the graphene film 320 is transferred thereto (e.g., FIGS. 2A-2E). The graphene film 320 may be a single sheet or multiple sheets and provide corrosion protection to the current collectors 310, 315 while not affecting their conductivity.

A cathode material 330 forms an electrode on one side of the device (on current collector 310) and an anode material 140 forms an electrode on an opposite side (on current collector 315). The cathode/anode materials 330, 340 may include, but are not limited to, graphite, lithium iron phosphate, nickel oxide, manganese oxide, titanium oxide and alkaline metal hydride. An electrolyte 350 is provided between the electrodes 330, 340. The electrolyte 350 may be, for example, a polymer gel, or a perforated or microporous polymeric membrane soaked in a liquid.

A load 360 is connected to the current collectors 310, 315. The device 300 may be, for example, a battery, a supercapacitor, or a fuel cell. As one skilled in the art would know, the fuel cell generates oxygen (not illustrated) between the current collector 310 and the cathode material 330 and hydrogen (not illustrated) between the current collector 315 and the anode material 340.

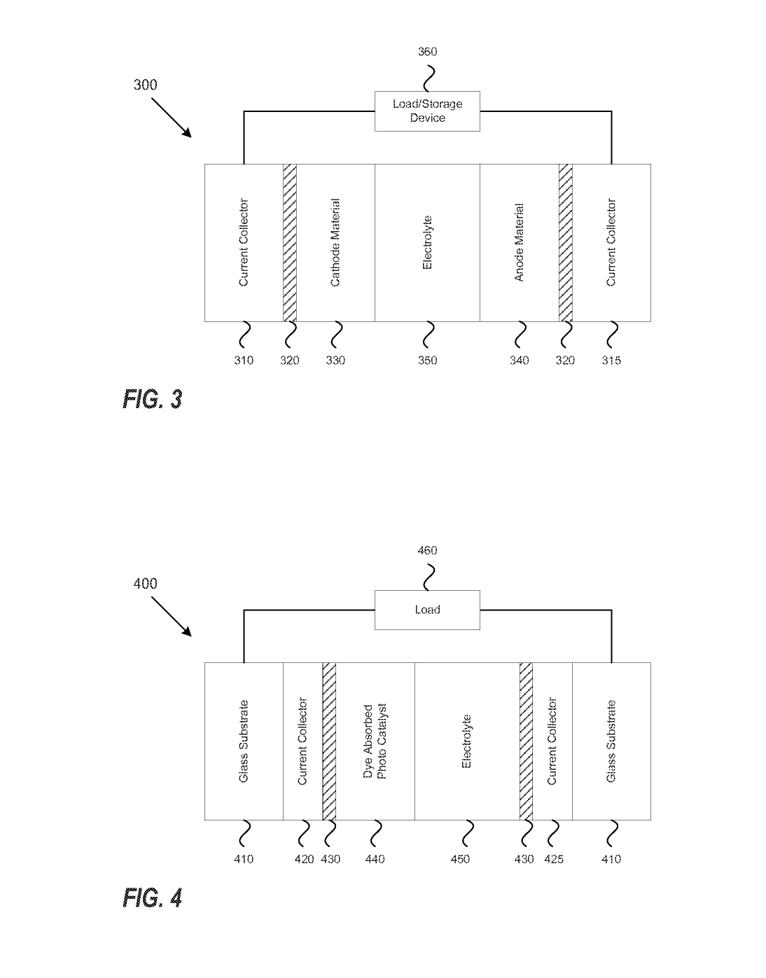

FIG. 4 illustrates a high level representation of an example energy conversion and/or storage device 400. The device 400 includes a pair of current collectors 420, 425 each mounted to a glass substrate 410 and having a surface covered with a graphene film 430. The current collectors 420, 425 are metallic conductor layers. The graphene film 430 may have been grown on the current collectors 420, 425 (e.g., FIGS. 1A-1B) or may have grown on other metallic layers and transferred thereto (e.g., FIGS. 2A-2E). The graphene film 430 may be a single sheet or multiple sheets and provide corrosion protection to the current collectors 420, 425 while not affecting their conductivity.

A dye absorbed photo catalyst 440 is formed on the current collector 420. An electrolyte 450 is provided between the current collectors 420, 425. The electrolyte 450 may be, for example, a polymer gel, or a perforated or microporous polymeric membrane soaked in a liquid. A load 460 is connected to the current collectors 420, 425. The device 400 may be, for example, a dye-sensitized solar cell.

Although the disclosure has been illustrated by reference to specific embodiments, it will be apparent that the disclosure is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

What is claimed:

1. An electrochemical energy conversion and storage device comprising:
a pair of current collectors;
a graphene film on each of the pair of current collectors, wherein the graphene film is impermeable to gas and ion diffusion and is to act as an anti-corrosion protective layer for the current collectors; and
an electrolyte between the pair of current collectors.

2. The device of claim 1, wherein the graphene film is a single graphene sheet.

3. The device of claim 1, wherein the graphene film is several layers of graphene sheets.

4. The device of claim 1, wherein at least one of the pair of current collectors is copper.

5. The device of claim 1, wherein at least one of the pair of current collectors is nickel.

6. The device of claim 1, wherein at least one of the pair of current collectors is iron.

7. The device of claim 1, wherein at least one of the pair of current collectors is aluminum.

8. The device of claim 1, wherein at least one of the pair of current collectors is lower quality metals.

9. The device of claim 1, further comprising an electrode material on the graphene film.

10. The device of claim 1, wherein the graphene film is located on one side of the current collectors.

11. The device of claim 1, wherein the graphene film is located on both sides of the current collectors.

12. The device of claim 1, further comprising an electrode material on at least the graphene film on one side of the current collectors.

13. The device of claim 1, further comprising an anode material formed on the graphene film on a first current collector of the pair of current collectors and a cathode material formed on the graphene film on a second current collector of the pair of current collectors.

14. The device of claim 1, further comprising a pair of glass substrates that the pair of current collectors are mounted to and a dye absorbed photo catalyst formed on the graphene film on a first current collector of the pair of current collectors.

15. The device of claim 1, wherein the device is a battery.

16. The device of claim 1, wherein the device is a supercapacitor.

17. The device of claim 1, wherein the device is a fuel cell.

18. The device of claim 1, wherein the device is a dye-sensitized solar cell.

19. A method for creating a corrosion and oxidation resistant current collector, the method comprising
obtaining a first metallic substrate, wherein the first metallic substrate is capable of growing a graphene layer thereon; and
growing a graphene film on the first metallic substrate using a chemical vapor deposition process, wherein the graphene film is impermeable to gas and ion diffusion and is to act as an anti-corrosion protective layer for the metallic substrate.

20. The method of claim 19, further comprising
coating an electrode material on the graphene film; and
using the first metallic substrate and the graphene film as the current collector in an electrochemical energy conversion and storage device.

21. The method of claim 19, wherein the obtaining a first metallic substrate includes obtaining a copper substrate.

22. The method of claim 19, wherein the obtaining a first metallic substrate includes obtaining a nickel substrate.

23. The method of claim 19, wherein the growing a graphene film includes growing the graphene film as a single graphene sheet.

24. The method of claim 19, wherein the growing a graphene film includes growing the graphene film as several layers of graphene sheets.

25. The method of claim 19, further comprising
forming a photoresist film on the graphene film;
removing the first metallic substrate;
attaching the graphene film to a second metal substrate; and
removing the photoresist film.

26. The method of claim 25, further comprising
coating an electrode material on the graphene film; and
using the second metallic substrate and the graphene film as the current collector in an electrochemical energy conversion and storage device.

27. The method of claim 25, wherein the forming a photoresist film includes forming a polymethyl methacrylate film.

28. The method of claim 25, wherein the removing the first metallic substrate includes electrochemical peeling the first metallic substrate from the graphene film.

29. The method of claim 25, wherein the attaching the graphene film to a second metal substrate includes attaching the graphene film to an iron substrate.

30. The method of claim 25, wherein the attaching the graphene film to a second metal substrate includes attaching the graphene film to an aluminum substrate.

31. The method of claim 25, wherein the attaching the graphene film to a second metal substrate includes attaching the graphene film to a lower quality metal substrate.

32. A corrosion and oxidation resistant current collector for use in an electrochemical energy conversion and storage device, the current collector comprising:
a metallic substrate;
a graphene film on the metallic substrate, wherein the graphene film is impermeable to gas and ion diffusion and is to act as an anti-corrosion protective layer for the metallic substrate.

33. The current collector of claim 32, further comprising an electrode material on the graphene film.

34. The current collector of claim 32, wherein the graphene film is a single graphene sheet.

35. The current collector of claim 32, wherein the graphene film is several layers of graphene sheets.

36. The current collector of claim 32, wherein the metallic substrate is copper.

37. The current collector of claim 32, wherein the metallic substrate is nickel.

38. The current collector of claim 32, wherein the metallic substrate is iron.

39. The current collector of claim 32, wherein the metallic substrate is aluminum.

40. The current collector of claim 32, wherein the metallic substrate is lower quality metals.
